(19) United States
(12) Patent Application Publication
(10) Pub. No.: US 2024/0057250 A1
(43) Pub. Date: Feb. 15, 2024

(54) METHOD AND SYSTEMS FOR COLD FORMING FEATURES ON FLEX CIRCUITS

(71) Applicant: KONINKLIJKE PHILIPS N.V., EINDHOVEN (NL)

(72) Inventor: FRANCIS KUSTI MAKIE, MELROSE, MA (US)

(21) Appl. No.: 18/266,898

(22) PCT Filed: Dec. 10, 2021
(86) PCT No.: PCT/EP2021/085165

§ 371 Date: Jun. 13, 2023

Related U.S. Application Data
(60) Provisional application No. 63/124,913, filed on Dec. 14, 2020.

(51) Int. Cl. H05K 1/02; H05K 3/02; H05K 3/38

(52) U.S. Cl. CPC H05K 1/028; H05K 3/022; H05K 3/386; H05K 2203/0495

(57) ABSTRACT

Systems and methods for cold forming one or more features (106) in a flex circuit (100). The flex circuit (100) includes: an electronic circuit (102) connected to a substrate (104). When the substrate (104) is in a planar state, one or more areas deemed to be bent (or otherwise augmented) in the cold forming process, are additionally and selectively plated with an extra layer of metal (108), such as copper, so that only these one or more areas are now capable of being cold formed into shapes accurately.

### FIELD OF THE DISCLOSURE

The present disclosure is directed generally to flexible electronics. More specifically, the present disclosure is directed to methods and systems for cold forming features in a flex circuit.

### BACKGROUND

Most current, common methods to form flex bends in a flex circuit use heated dies to form the bends. Heated dies can damage internal and external adhesive, insulation materials, solder joints, and other components used in the flex design. Hot dies can reach temperatures as high as 400° F. Such high temperatures can burn an operator and require a substantial cool down period, both adding to handling issues and cost for creating the flex circuit. Other issues with hot dies include that hot dies can anneal materials and damage high bond acrylic contact adhesives which may be used to bond the flex circuit to a complex shaped part. These issues limit the flexibility required to design flex circuits for specific applications in various devices.

Thus, there is a need in the art for methods and systems for forming flex bends in a flex circuit.

### SUMMARY OF THE DISCLOSURE

The present disclosure is directed to inventive methods and systems for cold forming one or more features in a flex circuit. More specifically, Applicant has recognized and appreciated that it would be beneficial to selectively plate a flex circuit with a material, such as copper, to provide the flex circuit with characteristics similar to sheet metal. Additionally, Applicant has recognized and appreciated that it would be beneficial to have a flex circuit with characteristics similar to sheet metal so that all the methods of manufacturing sheet metal are available to flex circuits. Exemplary methods of manufacturing sheet metal include cold forming with a complex die set, which achieves the goals of reducing handling issues and damage to components of the flex circuit and increasing the customization of the geometry of the flex circuit.

Generally, in example one, a cold formed flex circuit is provided. The flex circuit includes an electronic circuit connected to a substrate. A material is selectively plated on one or more areas on the substrate when the substrate is in a planar state. The one or more areas selectively plated with the material are cold formed into one or more features in the substrate when the substrate is moved from the planar state to a non-planar state.

In embodiments, example one may be combined with example two, wherein the substrate is composed of a polyamide layer, an adhesive layer, and a metal layer.

In embodiments, examples one or two may be combined with example three, wherein the material is an additional layer of copper.

In embodiments, examples one, two, or three may be combined with example four, wherein the one or more features is a bend, coining, or a shape formed in the substrate.

Generally, in example five, a method for cold forming a flex circuit is provided. The method includes selectively plating a material on one or more areas of the flex circuit when the flex circuit is in a planar state; and cold forming one or more features in the flex circuit at the one or more areas selectively plated with the material such that the flex circuit is moved from the planar state to a non-planar state.

In embodiments, example five may be combined with example six, wherein the method also includes providing a machine with a cold die set attached to a clamping mechanism; placing the flex circuit in the planar state on the machine; and forcing the cold die set against the flex circuit in the planar state, cold forming the flex circuit in the planar state into a non-planar state.

In embodiments, example six may be combined with example seven, wherein the cold die set comprises one or more dies, each having one or more complementary features matching the one or more features of the flex circuit in the non-planar state.

In embodiments, example seven may be combined with example eight, wherein the step of forcing the cold die set against the flex circuit in the planar state includes the step of cold forming the one or more features in the flex circuit in the non-planar state with the one or more complementary features of the one or more dies.

In embodiments, examples five, six, seven, or eight may be combined with example nine, wherein the one or more features is a bend, coining, or a shape cold formed in the flex circuit in the non-planar state.

In embodiments, examples five, six, seven, eight, or nine may be combined with example ten, wherein the flex circuit includes an electronic circuit connected to a substrate.

In embodiments, example ten may be combined with example eleven, wherein the substrate is composed of a polyamide layer, an adhesive layer, and a metal layer.

In embodiments, examples five, six, seven, eight, nine, ten, or eleven may be combined with example twelve, wherein the material is metal.

In embodiments, examples five, six, seven, eight, nine, ten, eleven, or twelve may be combined with example thirteen, wherein the material is copper.

In embodiments, examples five, six, seven, eight, nine, ten, eleven, twelve, or thirteen may be combined with example fourteen, wherein the flex circuit is a battery door flex circuit.

In embodiments, examples six, seven, or eight may be combined with example fifteen, wherein the step of forcing the cold die set against the flex circuit in the planar state, cold forming the flex circuit in the planar state into a non-planar state is completed in less than or equal to 30 seconds.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. These and other aspects of the various embodiments will be apparent from and elucidated with reference to the embodiment(s) described hereinafter.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the various embodiments.

FIG. 1 is an example flex circuit in a planar state, in accordance with aspects of the present disclosure;

FIG. 2 is an elevated side view of an example flex circuit in a non-planar state, in accordance with aspects of the present disclosure;

FIG. 3 is a perspective view of an example flex circuit in a non-planar state, in accordance with aspects of the present disclosure;

FIG. 4 is another perspective view of an example flex circuit in a non-planar state, in accordance with aspects of the present disclosure;

FIG. 5 is a side view of an example flex circuit in a non-planar state, in accordance with aspects of the present disclosure;

FIG. 6 is a front view of an example flex circuit in a non-planar state, in accordance with aspects of the present disclosure;

FIG. 7 is a bottom view of an example flex circuit in a non-planar state, in accordance with aspects of the present disclosure;

FIG. 8 is a top, perspective view of an example flex circuit in a non-planar state, in accordance with aspects of the present disclosure;

FIG. 9 is a perspective view of an example machine for cold forming one or more features in a flex circuit, in accordance with aspects of the present disclosure;

FIG. 10 is an exploded view of an example complex forming die set, in accordance with aspects of the present disclosure;

FIG. 11 is a perspective view of an example flex circuit implemented in an example battery door, in accordance with aspects of the present disclosure; and

FIG. 12 is another perspective view of an example flex circuit implemented in an example battery door, in accordance with aspects of the present disclosure.

### DETAILED DESCRIPTION OF EMBODIMENTS

The present disclosure describes various embodiments and implementations of systems and methods for cold forming one or more features in a flex circuit. More specifically, Applicant has recognized and appreciated that it would be beneficial to selectively plate a flex circuit with a material, such as copper, to provide the flex circuit with characteristics similar to sheet metal. Additionally, Applicant has recognized and appreciated that it would be beneficial to have a flex circuit with characteristics similar to sheet metal so that all the methods of manufacturing sheet metal are available to flex circuits. Exemplary methods of manufacturing sheet metal include cold forming with a complex die set, which achieves the goals of reducing handling issues and damage to components of the flex circuit and increasing the customization of the geometry of the flex circuit.

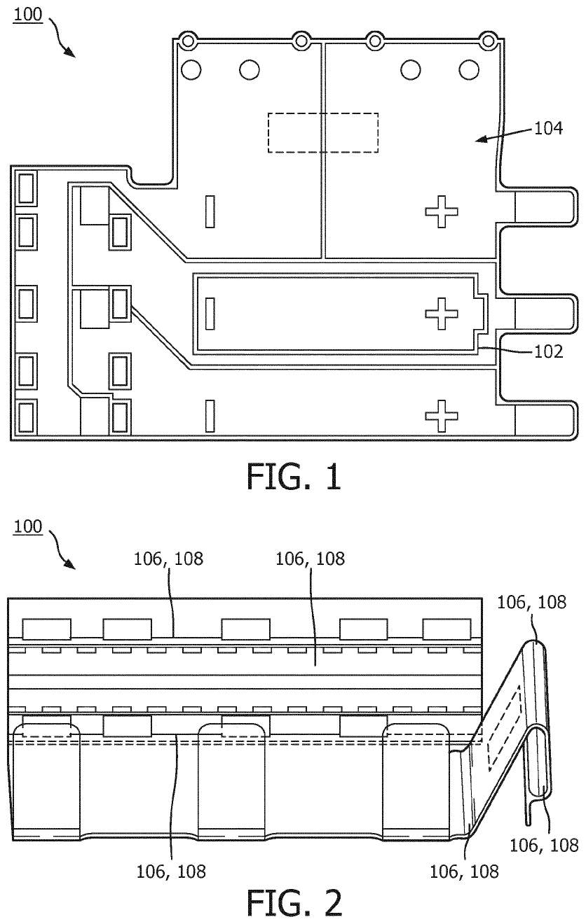

Referring to FIG. 1, an example flex circuit 100 in a planar state is provided. Flex circuit 100 is shown substantially flat in the planar state. Flex circuit 100 can be any flexible electronics having electronic circuits 102 mounted or otherwise attached to a substrate 104. Generally, substrate 104 is comprised of flexible plastic. According to an embodiment, substrate 104 is composed a polyamide layer, an adhesive layer, and a metal layer. Flex circuit 100 shown in FIG. 1 is a battery door flex circuit. Specifically, flex circuit 100 shown in FIG. 1 is a AA battery door flex circuit designed for implementation in a battery door. It is desirable to form complex shapes and precise angled bends in flex circuit 100 in the exact 3D space as the mating parts and design requirements of a device. For example, a battery door or other housing for flex circuit 100 may have bends or other non-planar topology that requires flex circuit 100 to have the same bends or other non-planar topology to fit closely therein. A close tolerance between flex circuit 100 and a housing is generally desirable; however, it is critical in medical devices where any gaps and crevices between the housing and flex circuit 100 can accumulate debris and germs.

FIG. 2 shows an elevated side view of an example flex circuit 100 in a non-planar state. Flex circuit 100 in the planar state in FIG. 1 has been formed or molded (according to methods described below) to achieve the non-planar state shown in FIG. 2. In FIG. 2, flex circuit 100 has one or more features 106. Features 106 can be complex shapes, precise bends, or any other augmentation of flex circuit 100. To form features 106, material 108 is first selectively plated on one or more areas of flex circuit 100 in the planar state, i.e., prior to formation or molding of flex circuit 100 into the non-planar state. Plated material 108 can be any metal. According to an exemplary embodiment, plated material 108 is copper, and, in particular, a thin (e.g., 0.002 inch) layer of copper. According to example methods described below, when flex circuit 100 is formed and molded, the one or more areas of flex circuit 100 plated with material 108 form one or more feature 106. In other words, flex circuit 100 is selectively plated with material 108 in the areas where features 106 (e.g., bend or coining) are desired.

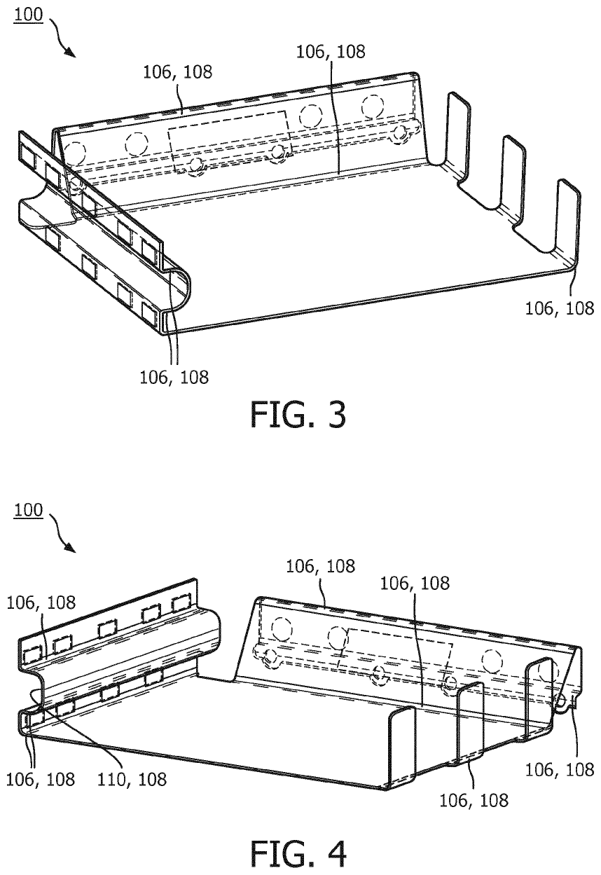

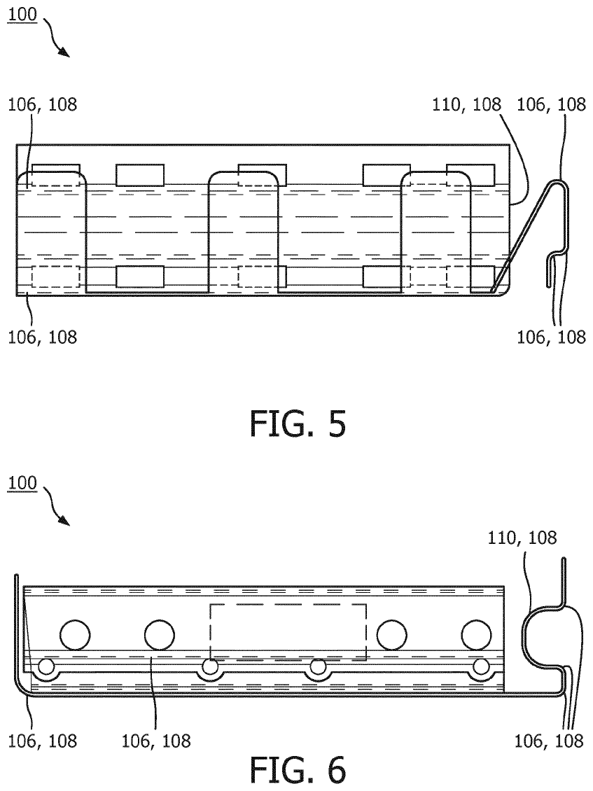

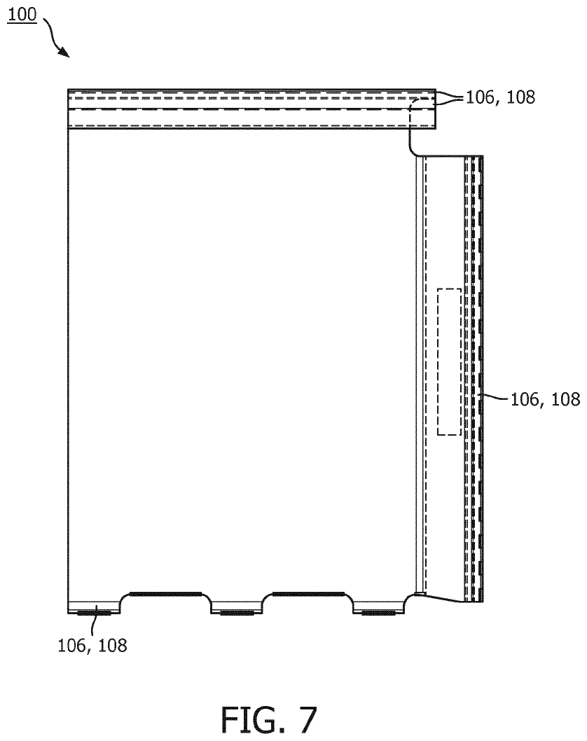

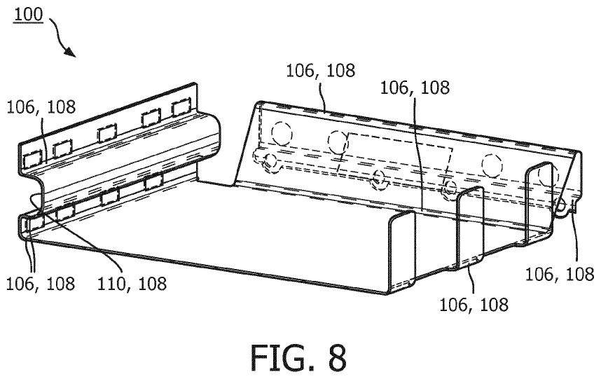

FIGS. 3-8 show various views of an example flex circuit 100 in the non-planar state. One or more features 106 of flex circuit 100 shown in FIGS. 3-8 were plated with material 108. In the depicted embodiment, features 106 are the one or more areas of flex circuit 100 (in the planar state) that have been first plated with material 108 and then formed or molded into a bend, curve, or other desired geometry. The extra layer of material 108 gives the areas of flex circuit 100 where features 106 are desired the strength to maintain the bend share without heat.

Specifically, the one or more areas of flex circuit 100 where features 106 are desired are plated with material 108, which causes flex circuit 100 to function similar to and/or have similar characteristics to sheet metal. Accordingly, many or all the methods of manufacturing sheet metal are available to flex circuit 100 plated with material 108. Therefore, an example manufacturing method, such as cold forming using a complex die set, can be used to create flex circuit 100 with complex shapes and precise angled bends. For example, in FIGS. 3-8, one of the one or more features 106 of flex circuit 100 is a semi-circular feature 110. Semi-circular feature 110 is coined from a die shaped to make the desired, custom semi-circular feature 110. Without the extra plating of material 108, flex circuit 100 would not be formable to a useful geometry without the use of heat. Furthermore, heat dies may not even be able to produce one or more features 106 (e.g., bends or coining) that are capable with extra plating of material 108 and cold forming.

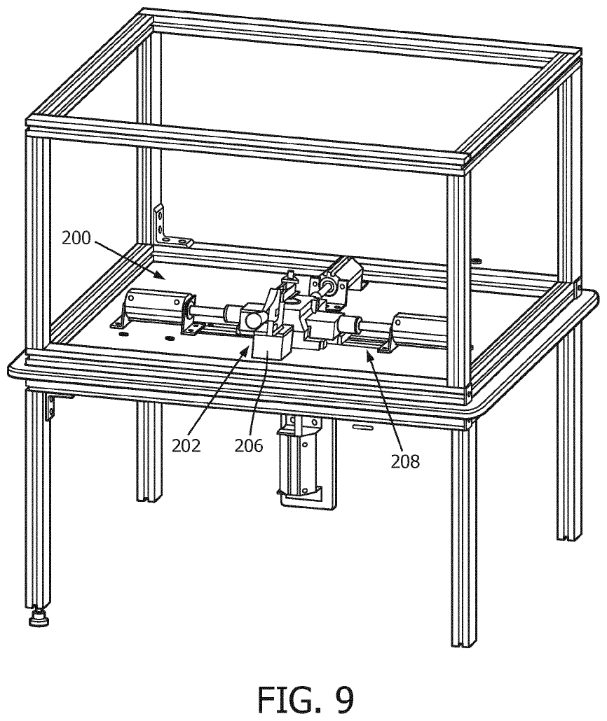

FIG. 9 shows a perspective view of an example machine 200 for cold forming one or more features 106 in flex circuit 100. Machine 200 uses a die set to cold form one or more features 106 in flex circuit 100 (FIGS. 2-8). Machine 200 creates all one or more features 106 in flex circuit 100 in one operation without the use of heat. In an example, machine 200 produces flex circuit 100 with all one or more features 106 in a 30-second cycle. Machine 200 can be hand-operated or fully automated.

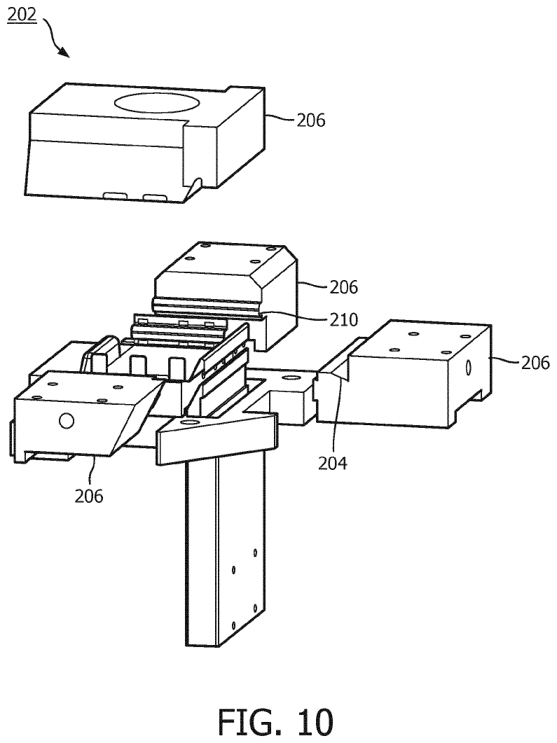

FIG. 10 shows an exploded view of a complex forming die set 202. Die set 202 is used to create formed flex circuit 100, as described above. As shown in FIG. 10, die set 202 comprises one or more complementary features 204 that match the geometry of one or more features 106 of flex circuit 100. The example die set 202 in FIG. 10 includes at least four die 206 (e.g., bending dies). Each of the four die 206 has at least one of the one or more complementary features 204. For example, in FIG. 10, one die 106 has a semi-circular complementary feature 210. In use, die set 202 is placed within machine 200, as shown in FIG. 9. Die set 202 is then forced against flex circuit 100 (in its planar state (FIG. 1)) using one or more clamping mechanisms 208 (FIG. 9). Flex circuit 100 is then cold formed according to the shape of complex die set 202. For example, semi-circular complementary feature 210 of die 206 creates semi-circular feature 110 of flex circuit 100 (FIGS. 3-8). One or more features 106 maintain the shape of one or more complementary features 204 of dies 206 due to the increased stiffness in the one or more area selectively plated with material 108.

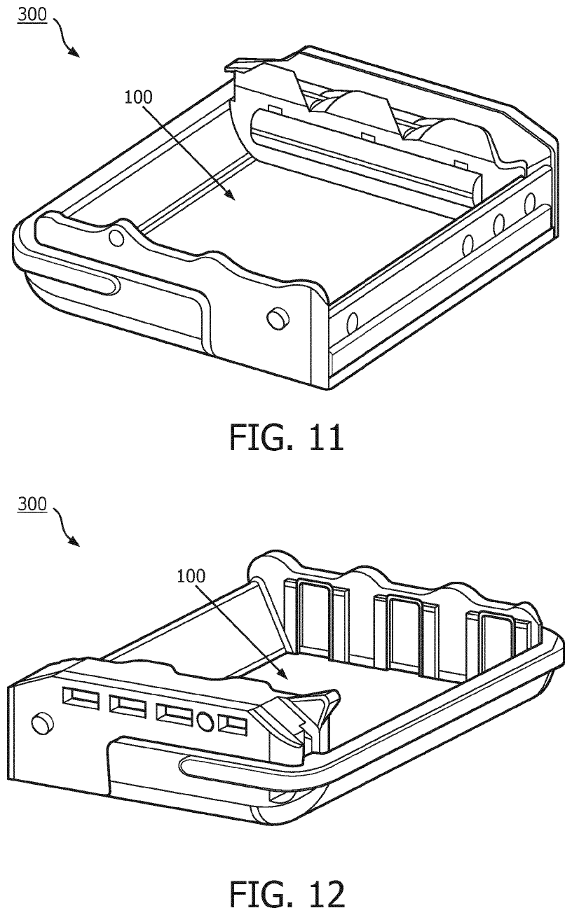

FIGS. 11-12 show perspective views of an example flex circuit 100 implemented into an example battery door 300. Cold-formed flex circuit 100 is incorporated into example battery door 300. As shown, the geometry of one or more features 106 of flex circuit 100 match the geometry of battery door 300 such that there is a very close tolerance between flex circuit 100 and battery door 300. The close tolerance between flex circuit 100 and battery door 300 not only ensures assembly functionality but also prevents large assembly gaps and crevices which can trap debris, germs and be difficult to clean. Cleanliness and functionality make flex circuit 100 and battery door 300 suitable for use as a medical device. Thus, although flex circuit 100 is shown with a geometry to closely match AA battery door 300, flex circuit 100 can be formed for any medical device requiring flexible electronics.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

1. A cold formed flex circuit, comprising:
an electronic circuit connected to a substrate; and
a material selectively plated on one or more areas on the substrate when the substrate is in a planar state;
wherein the one or more areas selectively plated with the material are cold formed into one or more features in the substrate when the substrate is moved from the planar state to a non-planar state.

2. The flex circuit of claim 1, wherein the substrate comprises a polyamide layer, an adhesive layer, and a metal layer.

3. The flex circuit according to claim 1, wherein the material comprises an additional layer of copper.

4. The flex circuit according to claim 1, wherein the one or more features is a bend, coining, or a shape formed in the substrate.

5. A method for cold forming a flex circuit, comprising:
selectively plating a material on one or more areas of the flex circuit when the flex circuit is in a planar state; and
cold forming one or more features in the flex circuit at the one or more areas selectively plated with the material such that the flex circuit is moved from the planar state to a non-planar state.

6. The method of claim 5, further comprising the steps of:
placing the flex circuit in the planar state on a machine with a cold die set attached to a clamping mechanism; and
forcing the cold die set against the flex circuit in the planar state, cold forming the flex circuit in the planar state into a non-planar state.

7. The method according to claim 6, wherein the cold die set comprises one or more dies, each having one or more complementary features matching the one or more features of the flex circuit in the non-planar state.

8. The method according to claim 7, wherein the step of forcing the cold die set against the flex circuit in the planar state includes the step of cold forming the one or more features in the flex circuit in the non-planar state with the one or more complementary features of the one or more dies.

9. The method according to claim 5, wherein the one or more features is a bend, coining, or a shape cold formed in the flex circuit in the non-planar state.

10. The method according to claim 5, wherein the flex circuit includes an electronic circuit connected to a substrate.

11. The method according to claim 10, wherein the substrate comprises a polyamide layer, an adhesive layer, and a metal layer.

12. The method according to claim 5, wherein the material is metal.

13. The method according to claim 5, wherein the material is copper.

14. The method according to claim 5, wherein the flex circuit is a battery door flex circuit.

15. The method according to claim 5, wherein the step of forcing the cold die set against the flex circuit in the planar state, cold forming the flex circuit in the planar state into a non-planar state is completed in less than or equal to 30 seconds.
